(19) United States
(12) Patent Application Publication
(10) Pub. No.: US 2006/0060847 A1
(43) Pub. Date: Mar. 23, 2006

(54) Silicon-insulator-silicon structure and method for fabricating the same

(75) Inventor: Dong-sik Shim, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/228,225

(22) Filed: Sep. 19, 2005

(30) Foreign Application Priority Data
Sep. 20, 2004 (KR) 2004-75246

(51) Int. Cl. H01L 29/06; H01L 21/461

(52) U.S. Cl. 257/49; 438/706; 438/719; 257/622

(57) ABSTRACT

A silicon-insulator-silicon structure with an insulator having a plurality of openings and a method for fabricating the same are provided. The silicon-insulator-silicon structure includes a lower silicon layer; an insulator formed on the lower silicon layer and having a plurality of openings; and an upper silicon layer formed on the insulator and etched at its predetermined region, wherein the opening of the insulator allows a material used for etching the upper silicon layer at its predetermined region, to move to the lower silicon layer. Accordingly, the silicon-insulator-silicon structure can provide the opening in the insulator, thereby not only preventing the upper silicon layer from being notched when the upper silicon layer is etched, but also relieving the stress of the silicon-insulator-silicon structure.

### CROSS-REFERENCE TO RELATED APPLICATIONS

This application claims benefit under 35 U.S.C. § 119 from Korean Patent Application No. 2004-75246 filed on Sep. 20, 2004, the entire content of which is incorporated herein by reference.

### BACKGROUND OF THE INVENTION

1. Field of the Invention

The present invention relates to a silicon-insulator-silicon structure. More particularly, the present invention relates to a silicon-insulator-silicon structure with an insulator having an opening.

2. Description of the Related Art

FIGS. 1A and 1B are sectional views illustrating a conventional silicon-insulator-silicon structure. FIG. 1A illustrates a conventional silicon-insulator-silicon structure, and FIG. 1B illustrates a silicon-insulator-silicon structure with a second silicon layer etched. At this time, an “A” region refers to a notch region.

Referring to FIGS. 1A and 1B, the conventional silicon-insulator-silicon structure includes a first silicon layer 1; an insulator 3 formed on the first silicon layer; and the second silicon layer 5 formed on the insulator 3.

In a case where the second silicon layer 5 is etched at its predetermined region, etching speed differs depending on the size of the etching region. In a case where the etching region is large, plasma, ions and the like are more greatly introduced for etching. Therefore, the second silicon layer 5 of the large etching region is etched at a higher speed than that of a small etching region.

Accordingly, a notch is caused at the large etching region, thereby excessively etching the second silicon layer 5 at both of the lower sides of the etching region, such as region “A” in FIG. 1B, due to the plasma, the ions and the like introduced even after the second silicon layer 5 is etched. The notch is caused by an excessive amount of plasma, ions and the like being introduced to etch the etching region, which is not completely etched at the upper silicon layer.

The conventional silicon-insulator-silicon structure has a drawback in that if an external force is applied to a notched material, a stress concentration phenomenon occurs, thereby causing a notch effect in which a notch portion is deformed or destroyed faster than other non-notch portions.

### SUMMARY OF THE INVENTION

Accordingly, it is an object of the present invention to provide a silicon-insulator-silicon structure whose insulator is opened at its predetermined region, thereby preventing an upper silicon layer from being notched due to its different etching speed.

The above object of the present invention is substantially realized by providing a silicon-insulator-silicon structure including: a lower silicon layer; an insulator formed on the lower silicon layer and having a plurality of openings; and an upper silicon layer formed on the insulator and etched at a predetermined region thereof, wherein the opening of the insulator allows a material used for etching the predetermined region of the upper silicon layer, to move to the lower silicon layer.

The opening of the insulator may have at least one of a hole shape and a line shape.

Additionally, the upper silicon layer may be dry-etched at the predetermined region.

In accordance with another aspect of the present invention, there is provided a method for fabricating a silicon-insulator-silicon structure, the method including the steps of: forming a lower silicon layer; forming an insulator having a plurality of openings on the lower silicon layer; and forming an upper silicon layer, which is etched at its predetermined region, on the insulator.

The opening of the insulator may have at least one of a hole shape and a line shape.

The opening of the insulator may be provided under the predetermined region of the upper silicon layer to allow a material used for etching the upper silicon layer at the predetermined region, to move to the lower silicon layer.

Additionally, the upper silicon layer may be dry-etched at the predetermined region.

### BRIEF DESCRIPTION OF THE DRAWINGS

The above aspects and features of the present invention will be more apparent by describing certain embodiments of the present invention with reference to the accompanying drawings, in which:

FIGS. 1A and 1B are sectional views illustrating a conventional silicon-insulator-silicon structure;

FIG. 2 is a sectional view illustrating a silicon-insulator-silicon structure according to an embodiment of the present invention;

FIGS. 3A and 3B respectively are plan views illustrating an insulator of a silicon-insulator-silicon structure according to an embodiment of the present invention;

FIG. 4 is a view illustrating a silicon-insulator-silicon structure of which the lower silicon layer is etched according to an embodiment of the present invention; and

FIG. 5 is a flowchart illustrating a method for fabricating a silicon-insulator-silicon structure according to an embodiment of the present invention.

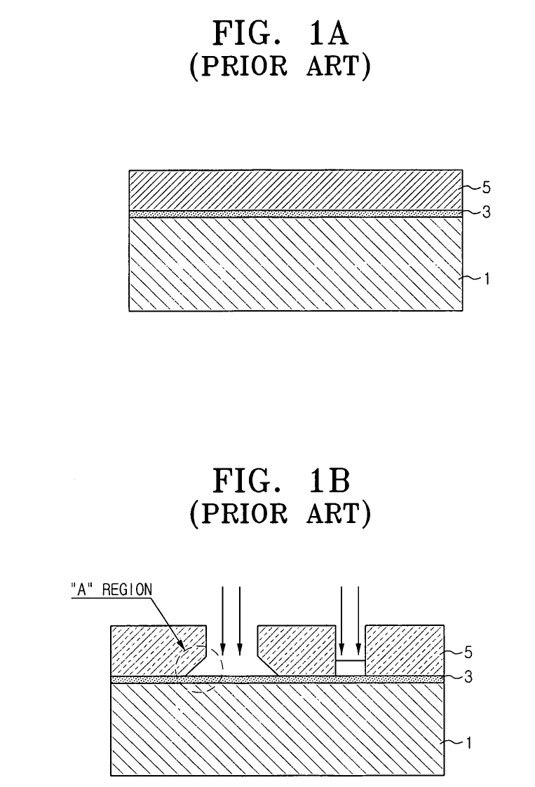

### DETAILED DESCRIPTION OF THE EXEMPLARY EMBODIMENTS

Exemplary embodiments of the present invention will be described in detail with reference to the annexed drawings. In the drawings, the same elements are denoted by the same reference numerals throughout the drawings. In the following description, detailed descriptions of known functions and configurations incorporated herein have been omitted for conciseness and clarity.

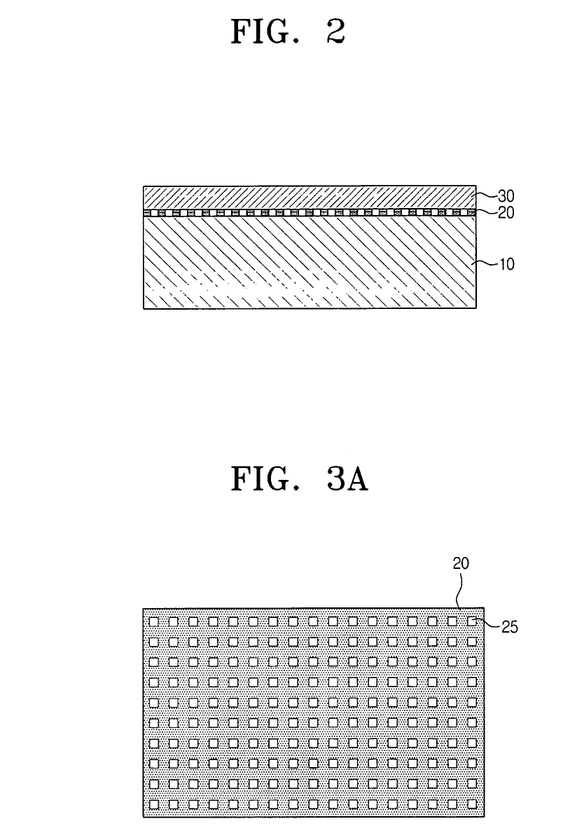

FIG. 2 is a sectional view illustrating a silicon-insulator-silicon structure according to an embodiment of the present invention.

Referring to FIG. 2, an insulator 20 having a plurality of openings is formed on a lower silicon layer 10. Additionally, an upper silicon layer 30 is formed on the insulator 20. The insulator 20 has the openings to prevent the upper silicon layer 30 from being notched, at the time of dry-etching, due to its etching speed being varied depending on the size of an etching region. In other words, in a case where the upper silicon layer 30 is first dry-etched at a specific region, the opening of the insulator 20, which is provided under the etching-completed specific region of the upper silicon layer 30, allows plasma, ions and the like for etching to pass toward the lower silicon layer 10. By doing so, the upper silicon layer 30 is prevented from being excessively etched, by excessive plasma and the like, at both lower sides of the etching-completed specific region.

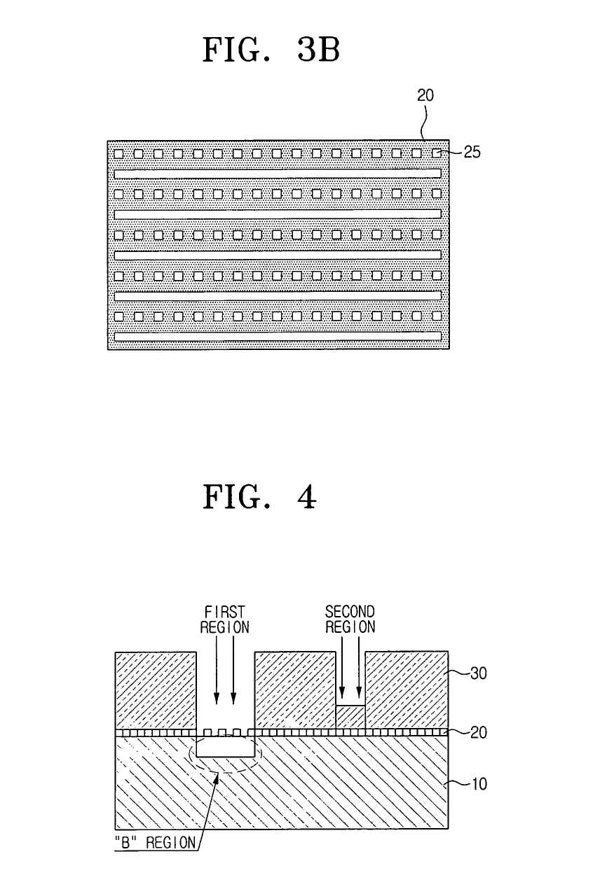

FIGS. 3A and 3B respectively are plan views illustrating the insulator 20 of the silicon-insulator-silicon structure according to an embodiment of the present invention. FIG. 3A is a view illustrating the insulator 20 having a plurality of hole-shaped openings 25, and FIG. 3B is a view illustrating the insulator having a plurality of hole-shaped openings and a plurality of line-shaped openings.

Referring to FIGS. 3A and 3B, the hole-shaped opening 25 and the line-shaped opening allows the passage of the plasma, ions and the like for dry-etching the upper silicon layer 30. Accordingly, the hole-shaped opening 25 and the line-shaped opening of the insulator 20 are positioned at the first etching-completed region among the etching regions of the upper silicon layer 30 to allow the passage of the plasma and the like toward the lower silicon layer 10.

Additionally, the opening of the insulator 20 can be variously shaped to allow the passage of the plasma and the like for etching the upper silicon layer 30 to the lower silicon layer 10. In other words, the insulator 20 can have variously shaped openings such as a hole-shaped opening, a line-shaped opening, and openings having both hole-shape and line-shape for allowing the plasma and the like to move to the lower silicon layer 10. However, the size of the opening of the insulator 20 should be properly controlled depending on the size of the silicon-insulator-silicon structure.

FIG. 4 is a view illustrating the silicon-insulator-silicon structure of which a lower silicon layer is etched according to an embodiment of the present invention. Here, the “B” region is a region at which the lower silicon layer 10 is etched using the plasma passing through the hole 25 of the insulator 20. Additionally, a first region and a second region are etching regions of the upper silicon layer 30.

Referring to FIG. 4, when the upper silicon layer 30 is reactive-etched, a greater amount of plasma is injected to the first region than to the second region. This is because the first region is larger than the second region. Accordingly, the etching speed of the first region is greater than the etching speed of the second region, and the insulator 20 of the first region is exposed to the exterior at a higher speed than at the second region. Even after the insulator 20 of the first region is exposed to the exterior, the second region of the upper silicon layer 30 is not completely etched. Accordingly, the plasma is continuously injected to the first region and the second region to etch the upper silicon layer 30 of the second region.

The plasma, which is injected to the first region after the upper silicon layer 30 of the first region is entirely etched, passes through the hole-shaped opening 25 of the insulator 20 to move to the lower silicon layer 10. Accordingly, the injected plasma etches the lower silicon layer 10 of the first region, that is, the lower silicon layer 10 of the “B” region. The opening provided in the insulator 20 allows the injected plasma to move to the lower silicon layer 10, thereby preventing the injected plasma from etching both lower sides of the first region of the upper silicon layer 30.

Additionally, even in the case where the upper silicon layer 30 is etched through a dry etching such as an ion beam etching as well as the reactive etching, the opening is provided in the insulator 20, thereby preventing a drawback caused by an etching speed difference.

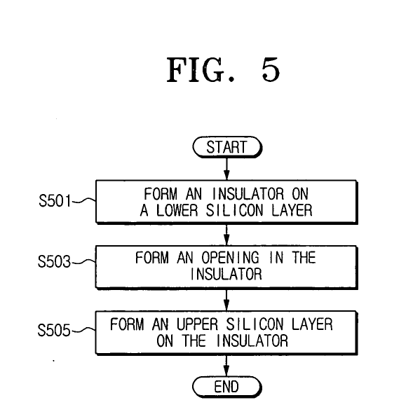

FIG. 5 is a flowchart illustrating a method for fabricating the silicon-insulator-silicon structure according to an embodiment of the present invention.

Referring to FIG. 5, the insulator 20 is formed on the lower silicon layer 10 (S501).

Next, the opening is provided in the insulator 20 (S503). The opening is to prevent the upper silicon layer 30 from being notched when the upper silicon layer 30 is dry-etched on the insulator 20, and relieve a stress caused by the material formed on the lower silicon layer 10.

Additionally, the opening may have a hole shape 25, a line shape or another shape. The opening is formed in the insulator 20 corresponding to the etching region of the upper silicon layer 30. The opening is shaped to allow the passage of a material such as plasma, ions and the like used for etching the upper silicon layer 30. The insulator 20 may also have the opening under a region other than the etching region of the upper silicon layer 30 to relieve the stress caused by the material formed on the lower silicon layer 10.

Additionally, the upper silicon layer 30 is formed on the insulator 20 having the opening (S505).

As described above, the inventive silicon-insulator-silicon structure provides an opening in the insulator, thereby not only preventing the upper silicon layer from being notched when the upper silicon layer is etched, but also relieving the stress of the silicon-insulator-silicon structure.

The foregoing embodiment and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. A silicon-insulator-silicon structure comprising:
a lower silicon layer;
an insulator formed on the lower silicon layer and having a plurality of openings; and
an upper silicon layer formed on the insulator and etched at a predetermined region thereof,
wherein the opening of the insulator allows a material used for etching the predetermined region of the upper silicon layer, to move to the lower silicon layer.

2. The structure as claimed in claim 1, wherein the opening of the insulator has at least one of a hole shape and a line shape.

3. The structure as claimed in claim 1, wherein the predetermined region of the upper silicon layer is etched by a dry etching.

4. A method for fabricating a silicon-insulator-silicon structure, the method comprising:
forming a lower silicon layer;
forming an insulator having a plurality of openings on the lower silicon layer; and
forming an upper silicon layer, which is etched at a predetermined region, on the insulator.

5. The method as claimed in claim 4, wherein the opening of the insulator has at least one of a hole shape and a line shape.

6. The method as claimed in claim 4, wherein the opening of the insulator is provided under the predetermined region of the upper silicon layer to allow a material used for etching the predetermined region of the upper silicon layer, to move to the lower silicon layer.

7. The method as claimed in claim 4, wherein the predetermined region of the upper silicon layer is etched by a dry etching.
